(19) United States
(12) Patent Application Publication
(10) Pub. No.: US 2025/0063721 A1
(43) Pub. Date: Feb. 20, 2025

(54) SEMICONDUCTOR DEVICE

(71) Applicant: Samsung Electronics Co., Ltd., Suwon-si (KR)

(72) Inventor: Changhyuck Sung, Suwon-si (KR)

(21) Appl. No.: 18/634,937

(22) Filed: Apr. 13, 2024

(30) Foreign Application Priority Data
Aug. 14, 2023 (KR) 10-2023-0106462

(51) Int. Cl. H10B 12/00

(52) U.S. Cl. CPC H10B 12/315; H10B 12/05; H10B 12/50

(57) ABSTRACT

A semiconductor device may include a channel structure, a gate insulating layer, a work function adjustment layer, and a word line. The channel structure may include an oxide semiconductor material. The gate insulating layer, the work function adjustment layer, and the word line may be sequentially formed on the channel structure.

### CROSS-REFERENCE TO RELATED APPLICATION(S)

This application is based on and claims priority under 35 USC § 119 to Korean Patent Application No. 10-2023-0106462, filed on Aug. 14, 2023, in the Korean Intellectual Property Office, the disclosure of which is incorporated by reference herein in its entirety.

### BACKGROUND

The inventive concept relates to semiconductor devices and, more particularly, to a semiconductor device including a vertical channel structure.

Advances in electronic technology have led to the rapid down-scaling of semiconductor devices, which in turn has resulted in the reduction of the size of DRAM devices. In DRAM devices having a 1T-1C structure in which one capacitor is connected to one transistor, a leakage current through a channel region gradually increases as the devices becomes smaller. To reduce the leakage current, a transistor using an oxide semiconductor material as a channel layer has been proposed.

### SUMMARY

The inventive concept provides a semiconductor device with improved electrical reliability of a transistor having a channel structure due to use of an oxide semiconductor material.

In addition, the disadvantage to be solved by the inventive concept is not limited to the disadvantage mentioned above, and other disadvantage may be clearly understood by those skilled in the art from the description below.

The inventive concept provides the following semiconductor device.

According to an aspect of the inventive concept, there is provided a semiconductor device including a substrate, a bit line extending in a first horizontal direction on the substrate, a channel layer disposed on the bit line and including a first portion extending in the first horizontal direction, and a second portion connected to the first portion, including a first sidewall and a second sidewall opposite to the first sidewall, and extending in a vertical direction perpendicular to an upper surface of the substrate, a gate insulating layer formed to conformally cover the first portion on an upper surface of the first portion of the channel layer and the second portion on the first sidewall of the second portion of the channel layer, a work function adjustment layer conformally formed on the gate insulating layer, and a word line disposed on a sidewall of the work function adjustment layer and extending in a second horizontal direction perpendicular to the first horizontal direction. The channel layer may include an oxide semiconductor material.

According to another aspect of the inventive concept, there is provided a semiconductor device including a substrate, a bit line extending in a first horizontal direction on the substrate, a mold insulating layer covering the bit line on the substrate and including a mold opening, a first cell transistor disposed on a first sidewall of the mold opening, and a second cell transistor disposed on a second sidewall of the mold opening, wherein each of the first cell transistor and the second cell transistor includes a channel layer disposed on the bit line and including a first portion extending in the first horizontal direction, and a second portion connected to the first portion and extending in a vertical direction perpendicular to an upper surface of the substrate, a work function adjustment layer disposed on the first portion and the second portion of the channel layer, a gate insulating layer located between the channel layer and the work function adjustment layer, a word line disposed on a sidewall of the work function adjustment layer and extending in a second horizontal direction perpendicular to the first horizontal direction, a contact disposed on the second portion of the channel layer, and a landing pad disposed on the contact. The channel layer may include an oxide semiconductor material.

According to another aspect of the inventive concept, there is provided a semiconductor device including a substrate, a peripheral circuit region disposed on the substrate, a plurality of peripheral circuits disposed in the peripheral circuit region, a plurality of lower conductive lines disposed in parallel to each other and respectively connected to the plurality of peripheral circuits, a mold insulation pattern disposed on the plurality of lower conductive lines and defining a transistor region extending long in a first horizontal direction, a plurality of channel structures arranged in a row in the first horizontal direction in the transistor region and each including a vertical channel portion facing a sidewall of the mold insulation pattern, a work function adjustment layer having a thickness of about 1 nm to about 20 nm in the transistor region and covering the plurality of channel structures, a gate insulating layer located between the plurality of channel structures and the work function adjustment layer, an upper conductive line disposed on the plurality of channel structures in the transistor region, having a sidewall facing the vertical channel portions of each of the plurality of channel structures, and extending long in a second horizontal direction perpendicular to the first horizontal direction, and a plurality of conductive contact patterns connected to the vertical channel portions of the plurality of channel structures respectively. The plurality of channel structures may include an oxide semiconductor material. The work function control layer may include a material having a work function of about 4.9 eV or more.

### BRIEF DESCRIPTION OF THE DRAWINGS

Embodiments will be more clearly understood from the following detailed description taken in conjunction with the accompanying drawings in which:

FIG. 1 is a layout diagram illustrating a semiconductor device according to example embodiments;

FIG. 2 is an enlarged layout diagram of a cell array region portion of FIG. 1 according to example embodiments;

FIG. 3 is a cross-sectional view of the semiconductor device taken along line A1-A1′ in FIG. 2 according to example embodiments; and

FIGS. 4 to 16 are cross-sectional views illustrating a method of manufacturing a semiconductor device according to example embodiments.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted.

The embodiments may be modified in various forms and various embodiments may be provided, and thus, some embodiments are illustrated in the drawings and described in detail. However, it should be understood that the embodiments are not limited in scope and include all modifications, equivalents, and replacements belonging to the concept and the technical scope of the inventive concept. In describing the embodiments, if a detailed description for a related known art is considered to unnecessarily divert the gist of the inventive concept, the detailed description has been omitted but would be understood by those skilled in the art.

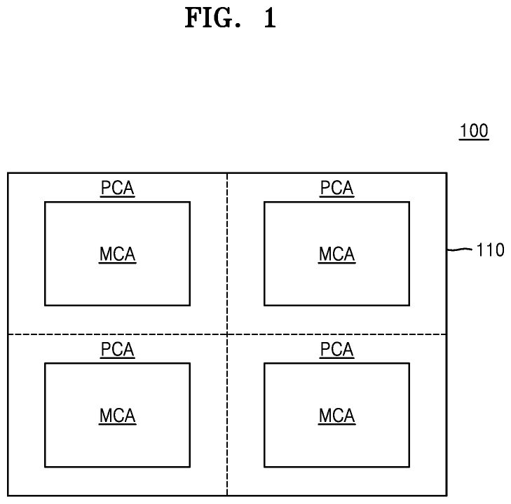

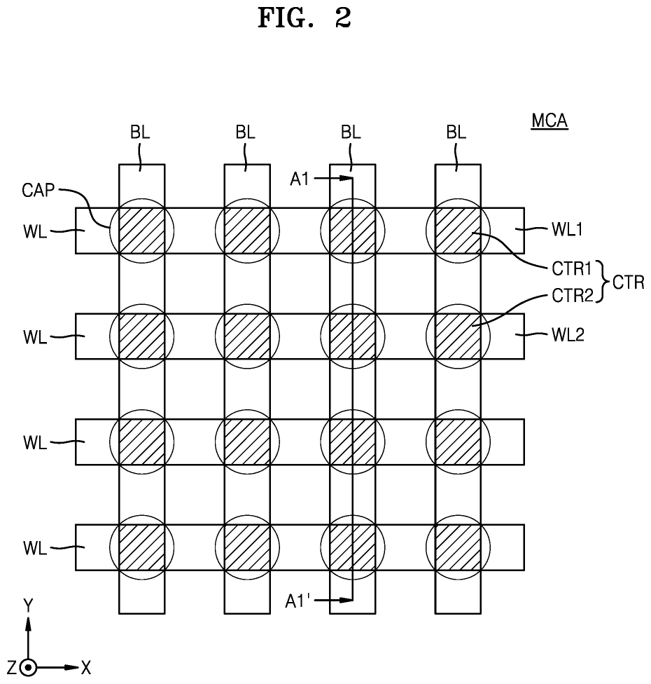

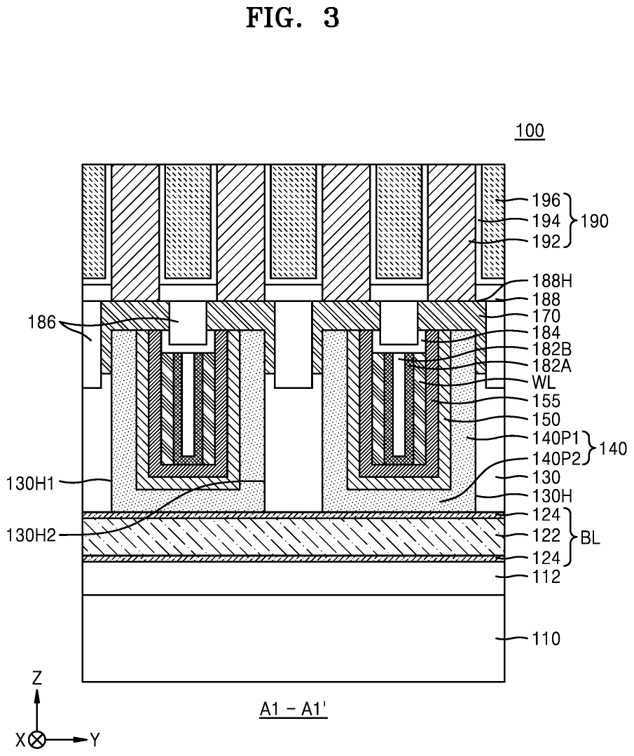

FIG. 1 is a layout diagram illustrating a semiconductor device 100 according to example embodiments. FIG. 2 is an enlarged layout diagram of a cell array region MCA portion of FIG. 1 according to example embodiments. FIG. 3 is a cross-sectional view of the semiconductor device 100 taken along line A1-A1′ of FIG. 2 according to example embodiments.

Referring to FIGS. 1 to 3, the semiconductor device 100 may include a substrate 110 including the cell array region MCA and a peripheral circuit region PCA. In some embodiments, the cell array region MCA may be a memory cell region of a dynamic random access memory (DRAM) device, and the peripheral circuit region PCA may be a core region or a peripheral circuit region of a DRAM device. For example, the peripheral circuit region PCA may include a plurality of peripheral circuit transistors (not shown) for transmitting signals and/or power to a memory cell array included in the cell array region MCA. In embodiments, the peripheral circuit transistors (not shown) may form various circuits, such as a command decoder, a control logic, an address buffer, a row decoder, a column decoder, a sense amplifier, and a data input/output (I/O) circuit.

As shown in FIG. 2, on the cell array region MCA of the substrate 110, a plurality of word lines WL extending in a first horizontal direction X and a plurality of bit lines BL extending in a second horizontal direction Y perpendicular to the first horizontal direction X may be arranged. The plurality of word lines WL extending in the first horizontal direction X may be arranged in parallel to each other. The plurality of bit lines BL extending in the second horizontal direction Y may be arranged in parallel to each other. A plurality of cell transistors CTR may be arranged at intersections of the word lines WL and the bit lines BL, respectively. A plurality of cell capacitors CAP may be arranged on the cell transistors CTR, respectively.

The word lines WL may include a first word line WL1 and a second word line WL2 alternately arranged in the second horizontal direction Y, and the cell transistors CTR may include a first cell transistor CTR1 and a second cell transistor CTR2 arranged alternately in the second horizontal direction Y. The first cell transistor CTR1 may be disposed on the first word line WL1, and the second cell transistor CTR2 may be disposed on the second word line WL2.

The first cell transistor CTR1 and the second cell transistor CTR2 may have a mirror symmetrical structure with respect to each other. For example, the first cell transistor CTR1 and the second cell transistor CTR2 may have a mirror symmetrical structure on a center line between the first cell transistor CTR1 and the second cell transistor CTR2 extending in the first horizontal direction X.

As shown in FIG. 3, a lower insulating layer 112 may be disposed on the substrate 110. The substrate 110 may include silicon, for example, single crystalline silicon, polycrystalline silicon, or amorphous silicon. In some other embodiments, the substrate 110 may include at least one selected from Ge, SiGe, SiC, GaAs, InAs, and InP. In some embodiments, the substrate 110 may include a conductive region, for example, a well doped with an impurity, or a structure doped with an impurity. The lower insulating layer 112 may include an oxide film, a nitride film, or combinations thereof.

The bit line BL extending in the second horizontal direction Y may be disposed on the lower insulating layer 112. In embodiments, the bit line BL may include Ti, TiN, Ta, TaN, Mo, Ru, W, WN, TiSiN, WSiN, polysilicon, or combinations thereof. For example, the bit line BL may include a conductive layer 122 and a conductive barrier layer 124 disposed on upper and lower surfaces of the conductive layer 122. A bit line insulating layer (not shown) extending in the second horizontal direction Y may be disposed on a sidewall of the bit line BL. For example, the bit line insulating layer may fill a space between two adjacent bit lines BL and may be formed at the same height as that of the bit lines BL.

A mold insulating layer 130 may be disposed on the bit line BL and the bit line insulating layer. The mold insulating layer 130 may include a plurality of mold openings 130H. Each of the mold openings 130H may include a first sidewall 130H1 and a second sidewall 130H2, and the first sidewall 130H1 and the second sidewall 130H2 may be apart from each other and extend in the first horizontal direction. An upper surface of the bit line BL may be exposed from a bottom of each of the mold openings 130H. The mold insulating layer 130 may include at least one of silicon oxide, silicon nitride, and silicon oxynitride.

A plurality of channel layers 140 may be disposed on inner walls of the mold openings 130H. Each of the channel layers 140 may include a first portion 140P1 extending on the bottom of each of the mold openings 130H in the second horizontal direction Y and a second portion 140P2 connected to the first portion 140P1 and disposed on the first sidewall 130H1 and the second sidewall 130H2 of each of the mold openings 130H. For example, each of the channel layers 140 may have a U-shaped vertical cross-section. The second portion 140P2 of each of the channel layers 140 may include first and second sidewalls that are opposite to each other, and the second sidewall may be in contact with the mold insulating layer 130. The second portion 140P2 may include two vertical portions within one mold opening 130H. Meanwhile, each of the channel layers 140 may have an upper surface disposed at a level higher than that of an upper surface of the mold insulating layer 130, and an upper portion of the second sidewall may not be surrounded by the mold insulating layer 130. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

In embodiments, the channel layers 140 may include an oxide semiconductor material. For example, the oxide semiconductor material may be formed of or include indium and may include at least one of, for example, InGaZnOx (IGZO), Sn-doped IGZO, W-doped IGZO, and InZnOx (IZO).

A gate insulating layer 150, a work function adjustment layer 155, and a word line WL may be sequentially disposed on the first sidewall of the second portion 140P2 of each of the channel layers 140. In an embodiment, each of the gate insulating layer 150 and the work function adjustment layer 155 may include a horizontal portion and two vertical portions within one mold opening 130H. For example, the gate insulating layer 150 may be conformally disposed on an upper surface of the first portion 140P1 and on the first sidewall of the second portion 140P2 of each of the channel layers 140. For example, the horizontal portion of the gate insulating layer 150 may be in contact with the upper surface of the first portion 140P1. The work function adjustment layer 155 may be disposed on the upper surface of the first portion 140P1 and the first sidewall of the second portion 140P2 of each of the channel layers 140, and the gate insulating layer 150 may be located between the work function adjustment layer 155 and the channel layers 140. For example, an upper surface of the horizontal portion of the gate insulating layer 150 may be in contact with a lower surface of the horizontal portion of the work function adjustment layer 155. The word line WL may be disposed on a sidewall of the work function adjustment layer 155.

The work function adjustment layer 155 may be in contact with the gate insulating layer 150 and the word line WL. For example, the work function adjustment layer 155 may be disposed between the gate insulating layer 150 and the word line WL on the first sidewall of the second portion 140P2 of each of the channel layers 140 within one mold opening 130H.

For example, each of the channel layers 140 having a U-shaped vertical cross-section may be disposed within one mold opening 130H, and two word lines WL may be located to be apart from each other on each of the channel layers 140 within one mold opening 130H. One word line WL may be disposed to face one second portion 140P2 of each of the channel layers 140, and the other word line WL may be disposed to face the other second portion 140P2 of each of the channel layers 140. One word line WL, one second portion 140P2 of each of the channel layers 140, and the gate insulating layer 150 and the work function adjustment layer 155 between the one second portion 140P2 of each of the channel layers 140 and the one word line WL may constitute the first cell transistor CTR1, and the other word line WL, the other second portion 140P2 of each of the channel layers 140, and the gate insulating layer 150 and the work function adjustment layer 155 between the other word line WL and the other second portion 140P2 of each of the channel layers 140 may constitute the second cell transistor CTR2. Accordingly, the first cell transistor CTR1 and the second cell transistor CTR2 may be arranged in a mirror symmetrical shape within one mold opening 130H.

In embodiments, the gate insulating layer 150 may include at least one selected from a high-k material having a dielectric constant higher than that of silicon oxide and a ferroelectric material. In some embodiments, the gate insulating layer 150 includes at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO).

In embodiments, the work function adjustment layer 155 may include a material having a work function of about 4.9 eV or more. The work function adjustment layer 155 may be formed of or include at least one selected from, for example, indium oxide (In₂O₃), titanium dioxide (TiO₂), molybdenum trioxide (MoO₃), or tungsten trioxide (WO₃). In embodiments, the work function adjustment layer 155 may be formed to have a thickness of about 1 nm to about 20 nm.

In embodiments, the word line WL may include Ti, TiN, Ta, TaN, W, WN, TiSiN, WSiN, polysilicon, or combinations thereof.

A contact formation region (not shown) may be disposed on an upper surface of the second portion 140P2 of each of the channel layers 140. A contact layer 170 may be disposed on the contact formation region. The contact layer 170 may cover the contact formation region and may extend onto the mold insulating layer 130. For example, the contact layer 170 may have a vertical cross-section in an inverted L shape. In embodiments, the contact layer 170 may include Ti, TiN, Ta, TaN, W, WN, TiSiN, WSiN, polysilicon, or combinations thereof.

An insulating liner 182A and a first insulating layer 182B may be disposed between two word lines WL within each of the mold openings 130H, and a second insulating layer 184 may be disposed on two word lines WL. In addition, a third insulating layer 186 may be disposed on both sidewalls of the contact layer 170. For example, the insulating liner 182A may include silicon nitride, and the first insulating layer 182B may include silicon oxide. The second insulating layer 184 and the third insulating layer 186 may include silicon nitride.

A bottom surface of the insulating liner 182A may be in contact with the work function adjustment layer 155 within one mold opening 130H. For example, the work function adjustment layer 155 may be disposed between the gate insulating layer 150 and the insulating liner 182A on the upper surface of the first portion 140P1 of each of the channel layers 140.

An etch stop layer 188 may be disposed on the contact layer 170 and the third insulating layer 186. The etch stop layer 188 may include an opening 188H, and an upper surface of the contact layer 170 may be exposed to the bottom of the opening 188H.

A capacitor structure 190 may be disposed on the etch stop layer 188. The capacitor structure 190 may include a lower electrode 192, a capacitor dielectric layer 194, and an upper electrode 196. A sidewall of the bottom of the lower electrode 192 may be disposed within the opening 188H of the etch stop layer 188, and the lower electrode 192 may extend in a vertical direction (a Z direction). The capacitor dielectric layer 194 may be disposed on a sidewall of the lower electrode 192, and the upper electrode 196 may cover the lower electrode 192 on the capacitor dielectric layer 194.

The semiconductor device 100 having a vertical channel structure according to the inventive concept may improve electrical reliability of the semiconductor device by inserting the work function adjustment layer 155 between the word line WL and the gate insulating layer 150. A threshold voltage of a cell transistor in the semiconductor device 100 may be positively shifted by insertion of the work function adjustment layer 155. For example, by insertion of the work function adjustment layer 155 in a cell transistor, an off-cell current Ioff of the cell transistor and a voltage VBB2 applied to a gate of the cell transistor may be reduced. Therefore, the reliability of semiconductor device may be improved by reducing the applied voltage VBB2.

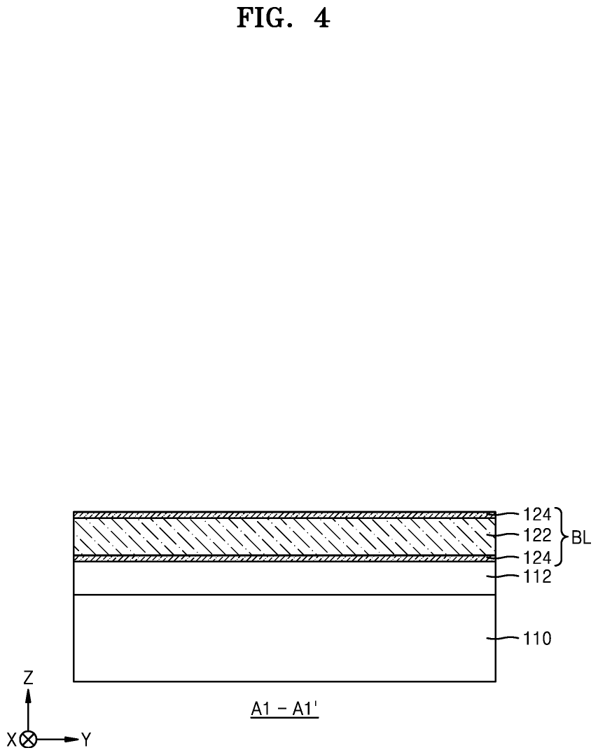

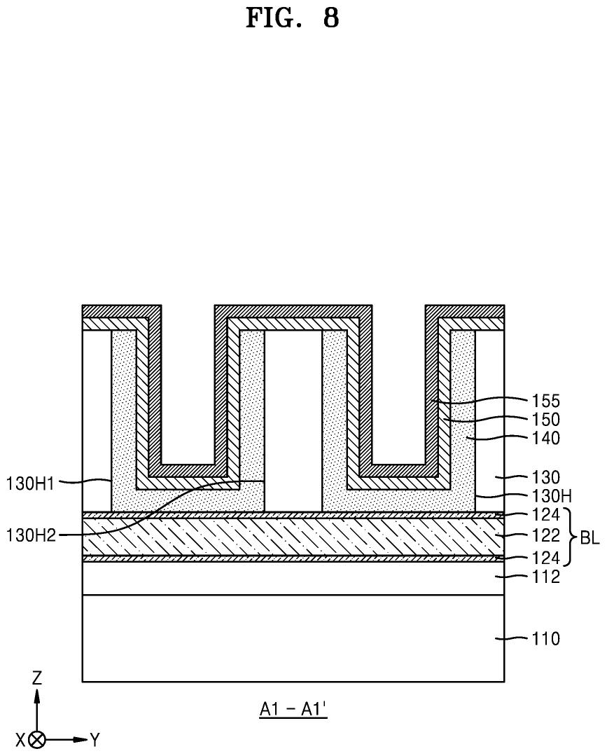

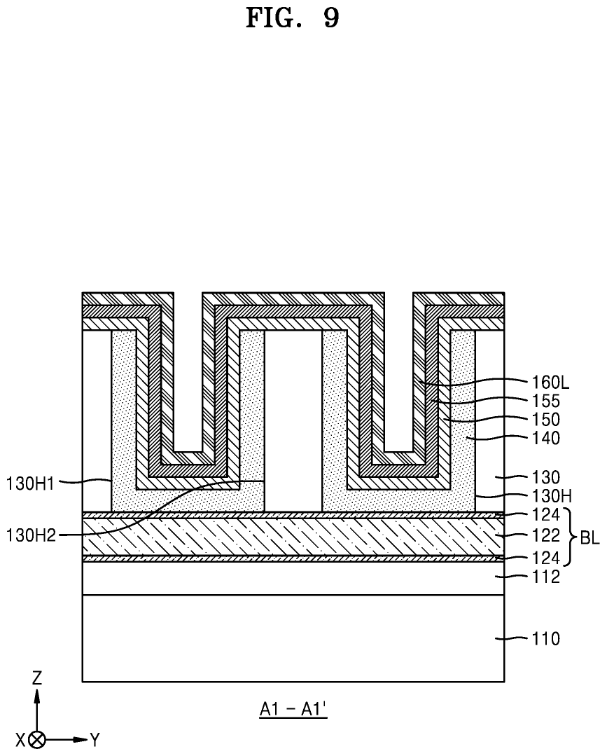

FIGS. 4 to 16 are cross-sectional views illustrating a method of manufacturing the semiconductor device 100 according to example embodiments. In FIGS. 4 to 16, the same reference numerals as those illustrated in FIGS. 1 to 3 denote the same components.

Referring to FIG. 4, the lower insulating layer 112 is formed on the substrate 110. Thereafter, the bit lines BL extending in the second horizontal direction (the Y direction) and the bit line insulating layer (not shown) filling the space between the bit lines BL may be formed on the lower insulating layer 112.

In embodiments, each of the bit lines BL may include a conductive barrier layer 124, a conductive layer 122, and a conductive barrier layer 124 being arranged sequentially. For example, the bit line insulating layer may be formed on the lower insulating layer 112 and patterned using a mask pattern (not shown) to form a bit line formation space (not shown), and the conductive barrier layer 124, the conductive layer 122, and the conductive barrier layer 124 may be sequentially formed in the bit line formation space. Thereafter, the bit lines BL may be formed by removing the conductive barrier layer 124, the conductive layer 122, and an upper side of the conductive barrier layer 124 until the upper surface of the bit line insulating layer is exposed.

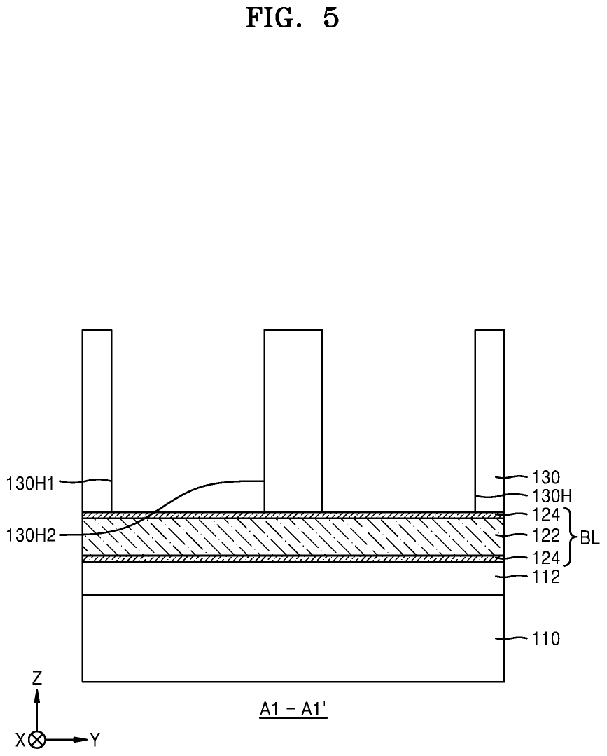

Referring to FIG. 5, the mold insulating layer 130 may be formed on the bit lines BL and the bit line insulating layer. The mold insulating layer 130 may be formed to have a relatively large height in the vertical direction (the Z direction) using at least one of silicon oxide, silicon nitride, and silicon oxynitride.

Thereafter, a mask pattern (not shown) may be formed on the mold insulating layer 130, and the mold openings 130H may be formed using the mask pattern as an etch mask. The upper surface of the bit line BL may be exposed from the bottom of each of the mold openings 130H. Each of the mold openings 130H may include first and second sidewalls 130H1 and 130H2 that are opposite to each other. In an embodiment, one mold opening 130H may be defined as a transistor region. For example, the first and second cell transistors CTR1 and CTR2 of FIG. 2 may be disposed in one mold opening 130H.

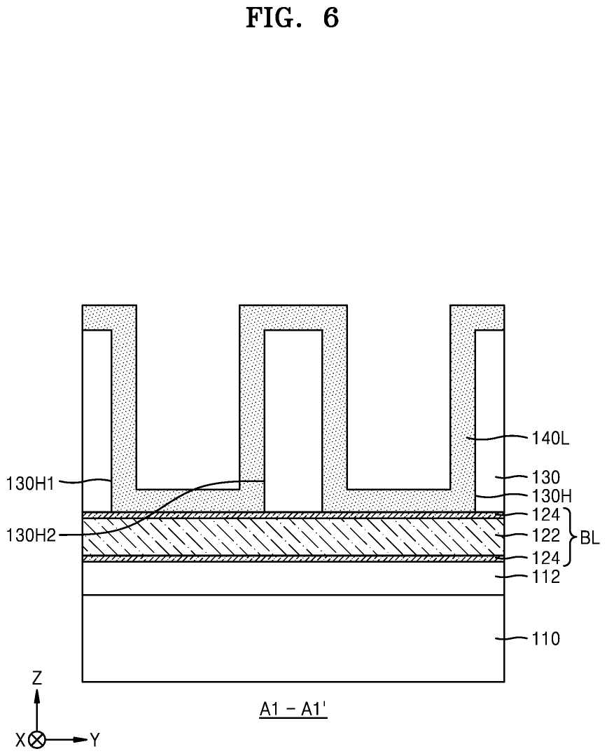

Referring to FIG. 6, a preliminary channel layer 140L may be formed on the mold insulating layer 130 to conformally cover the inner wall of each of the mold openings 130H. The preliminary channel layer 140L may be formed in a row in the second horizontal direction Y.

In embodiments, the preliminary channel layer 140L may be formed using an oxide semiconductor material. For example, the oxide semiconductor material may be formed of or include indium and may include, for example, at least one of InGaZnOx (IGZO), Sn-doped IGZO, W-doped IGZO, and IZO.

In embodiments, the preliminary channel layer 140L may be formed using at least one of a chemical vapor deposition (CVD) process, a low pressure CVD process, a plasma enhanced CVD process, a metal organic CVD (MOCVD) process, and an atomic layer deposition process.

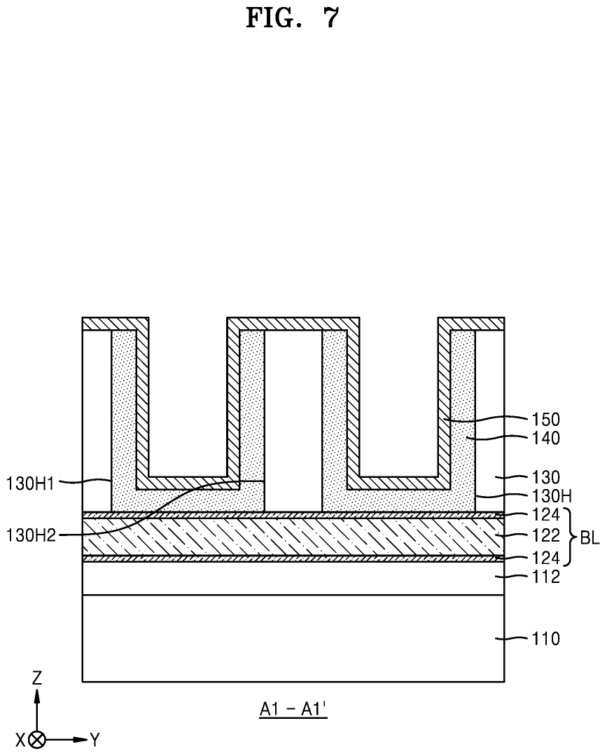

Referring to FIGS. 7, 8, and 9, the gate insulating layer 150, the work function adjustment layer 155, and the gate electrode layer 160L may be sequentially formed on the channel layers 140 in FIG. 6.

The gate insulating layer 150 may be disposed on the channel layers 140. For example, a horizontal portion (i.e., the first portion 140P1) of each of the channel layers 140 may include an upper surface coplanar with a lower surface of a horizontal portion of the gate insulating layer 150 within one mold opening 130H.

The gate insulating layer 150 may include at least one selected from a high-k material having a dielectric constant higher than that of silicon oxide and a ferroelectric material. In some embodiments, the gate insulating layer 150 includes at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

In embodiments, the work function adjustment layer 155 may include a material having a work function of 4.9 eV or more. The work function adjustment layer 155 may be formed of or include at least one selected from, for example, indium oxide (In₂O₃), titanium dioxide (TiO₂), molybdenum trioxide (MoO₃), and tungsten trioxide (WO₃). In embodiments, the work function adjustment layer 155 may be formed to have a thickness of about 1 nm to about 20 nm.

In embodiments, the gate electrode layer 160L may be formed using Ti, TiN, Ta, TaN, W, WN, TiSiN, WSiN, polysilicon, or combinations thereof.

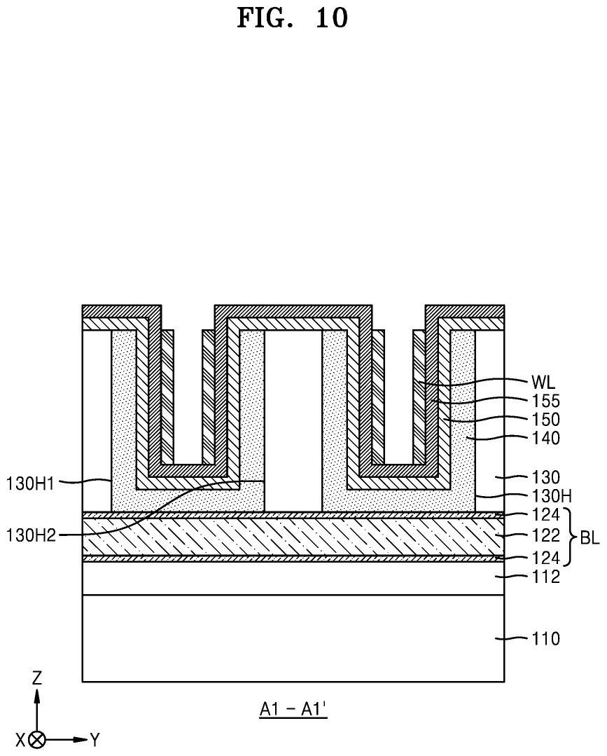

Referring to FIG. 10, an anisotropic etching process may be performed on the gate electrode layer 160L to remove a portion of the gate electrode layer 160L disposed on the bottom of each of the mold openings 130H and a portion of the gate electrode layer 160L disposed on the work function adjustment layer 155 within each of the mold openings 130H, and portions of the gate electrode layer 160L may remain on the first sidewall 130H1 and the second sidewall 130H2 of each of the mold openings 130H. Meanwhile, a portion of the gate electrode layer 160L disposed on the upper surface of the mold insulating layer 130 may also be removed by the anisotropic etching process.

For example, the gate electrode layer 160L may be separated into two word lines WL respectively disposed on the first and second sidewalls 130H1 and 130H2 of each of the mold openings 130H.

Although not shown, the work function adjustment layer 155 may also be etched in the above process. For example, when the portions of the gate electrode layer 160L disposed on the upper surface of the mold insulating layer 130 is removed, portions of the work function adjustment layer 155 disposed on the bottom of each of the mold openings 130H and disposed on the gate insulating layer 150 within each of the mold openings 130H may be removed, and a portion of the work function adjustment layer 155 may remain on the first sidewall 130H1 and the second sidewall 130H2 of each of the mold openings 130H. In this case, within each of the mold openings 130H, an upper surface of the work function adjustment layer 155 may be coplanar with an upper surface of the word line WL, and a lower surface of the work function adjustment layer 155 may be coplanar with a lower surface of the word line WL. However, the inventive concept is not limited thereto, and the work function adjustment layer 155 may not be etched but remain during the above process.

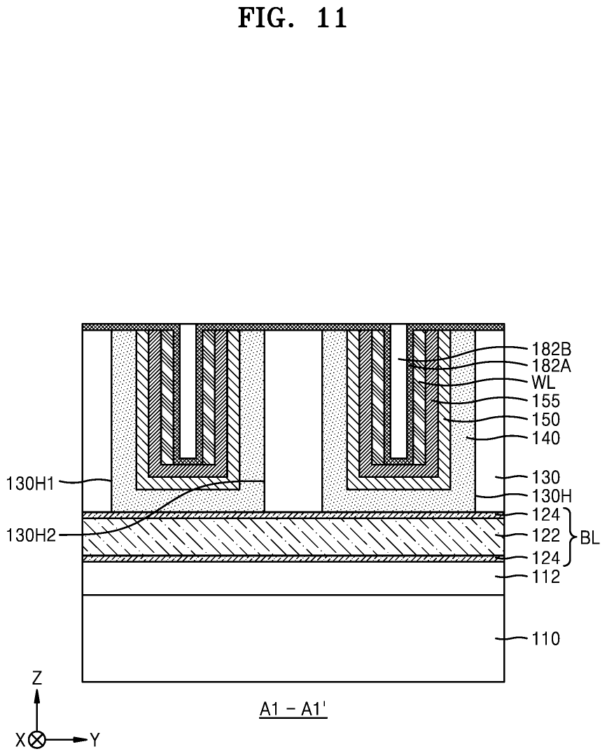

Referring to FIG. 11, portions of the gate insulating layer 150 and the work function adjustment layer 155 disposed on the upper surface of the mold insulating layer 130 may be removed by an etch-back process or a planarization process. In an embodiment, the uppermost surface of the second portion 140P2 of each of the channel layers 140 and the uppermost surface of the vertical portions of the gate insulating layer 150 may be disposed at the same vertical level. The insulating liner 182A and the first insulating layer 182B may be formed within one mold opening 130H. The insulating liner 182A and the first insulating layer 182B may be disposed between two adjacent word lines WL, and the insulating liner 182A may be disposed on the upper surface of the channel layers 140 and the upper surface of the mold insulating layer 130. For example, the insulating liner 182A may be disposed on the upper surface of the second portion 140P2 of each of the channel layers 140.

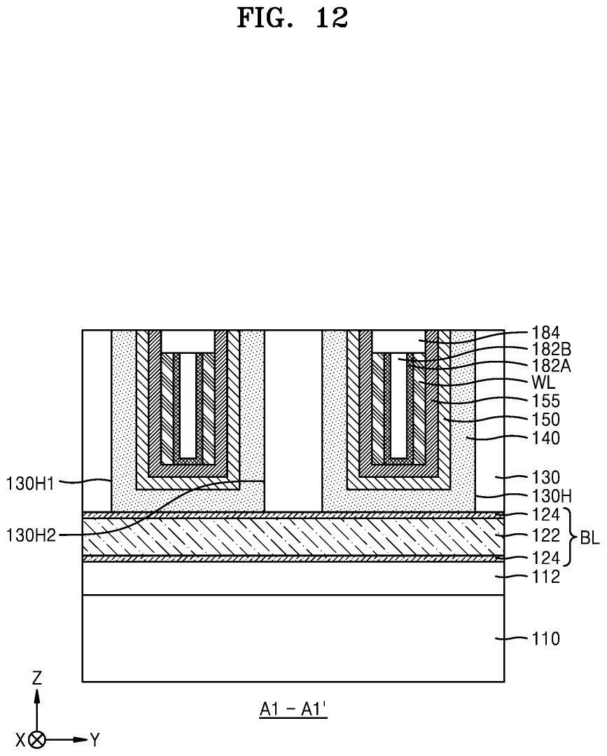

Referring to FIG. 12, a portion of the insulating liner 182A disposed on the upper surface of the mold insulating layer 130 may be removed through an etch-back process or a planarization process, leaving the channel layers 140 within the mold openings 130H.

Each of the channel layers 140 having a U-shaped vertical cross-section may be formed within one mold opening 130H through the etch-back process or the planarization process. In addition, the upper surface of the mold insulating layer 130 may be exposed.

In embodiments, each of the channel layers 140 may include the first portion 140P1 extending in the second horizontal direction (the Y direction) and the second portion 140P2 connected to both ends of the first portion 140P1 and extending in the vertical direction (the Z direction). The first sidewall of the second portion 140P2 may be surrounded by the gate insulating layer 150, and the second sidewall of the second portion 140P2 may be surrounded by the mold insulating layer 130. In addition, the upper surface of each of the channel layers 140 may be disposed at the same level as that of the upper surface of the mold insulating layer 130.

Thereafter, an upper portion of the word line WL disposed within one mold opening 130H may be removed through an etch-back process. During the etch-back process, an upper portion of the insulating liner 182A and an upper portion of the first insulating layer 182B may also be removed. During the etch-back process, a portion of the work function adjustment layer 155 may also be removed, but the inventive concept is not limited thereto. For example, the work function adjustment layer 155 may be not removed when the upper portion of the insulating liner 182A and the upper portion of the first insulating layer 182B are removed.

Thereafter, the second insulating layer 184 may be formed to fill the entrance of each of the mold openings 130H. The second insulating layer 184 may be disposed on the upper surfaces of the word line WL, the insulating liner 182A, and the first insulating layer 182B and have a flat bottom surface.

Accordingly, the first cell transistor CTR1 and the second cell transistor CTR2 may be formed within one mold opening 130H. The first cell transistor CTR1 and the second cell transistor CTR2 may be arranged to have a mirror symmetry with respect to each other.

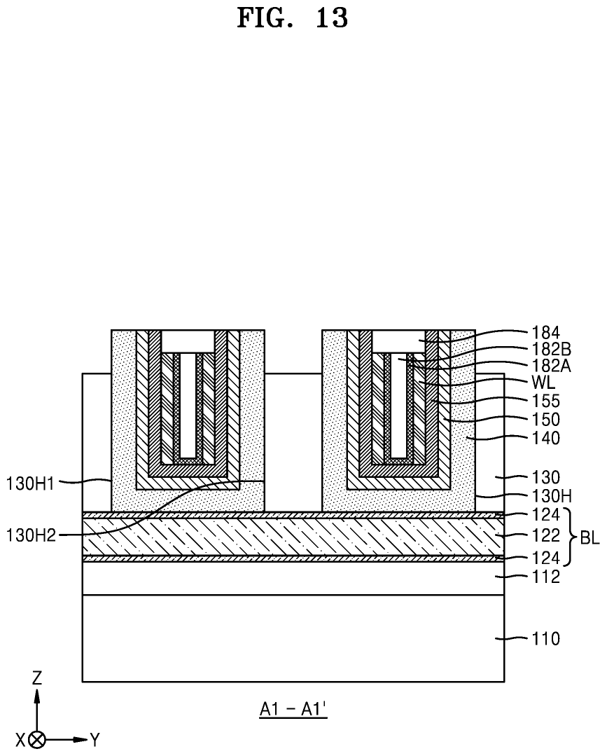

Referring to FIG. 13, a recess process may be performed on the upper surface of the mold insulating layer 130 to remove an upper portion of the mold insulating layer 130. As a result of the recess process, the upper surface of the mold insulating layer 130 may be disposed at a level lower than the upper surface of each of the channel layers 140, and an upper portion of the second sidewall of the second portion 140P2 of each of the channel layers 140 may be exposed to the outside of the mold insulating layer 130.

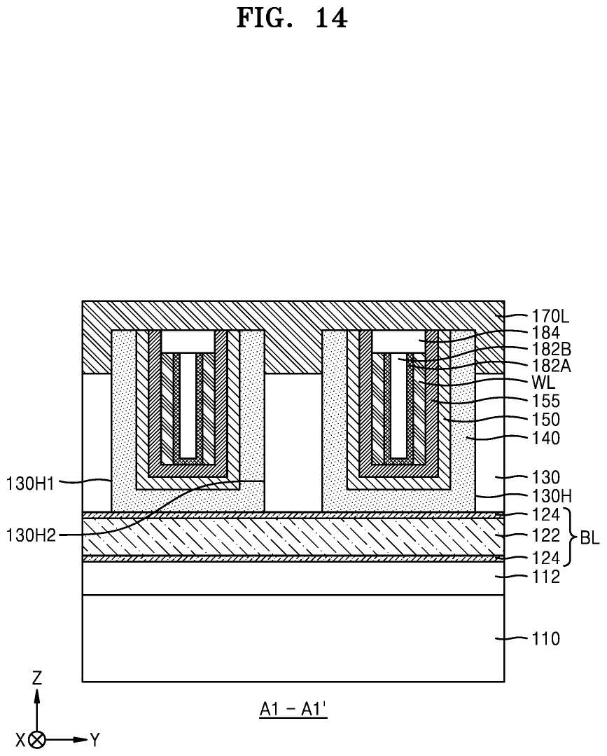

Referring to FIG. 14, a surface treatment process may be performed on the exposed second sidewall of the second portion 140P2 of each of the channel layers 140 and/or upper surface of the first portion 140P1 of each of the channel layers 140 to form a contact formation region (not shown), and the contact conductive layer 170L may be formed on the contact formation region, the mold insulating layer 130, and the second insulating layer 184.

In embodiments, the contact conductive layer 170L may include Ti, TiN, Ta, TaN, W, WN, TiSiN, WSiN, polysilicon, or combinations thereof.

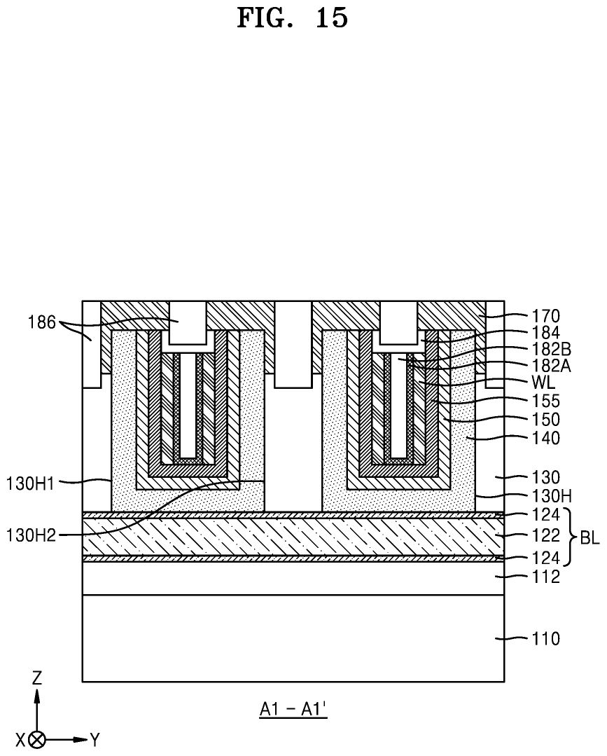

Referring to FIG. 15, a mask pattern (not shown) may be formed on the contact conductive layer 170L, a portion of the contact conductive layer 170L may be removed using the mask pattern to form the contact layer 170, and the third insulating layer 186 may be formed in a region from which the contact conductive layer 170L has been removed.

In embodiments, the third insulating layer 186 may be formed using silicon nitride. In addition, the sidewall of the contact layer 170 may be surrounded by the third insulating layer 186, and the bottom surface of the contact layer 170 may cover the contact formation region and extend onto the mold insulating layer 130.

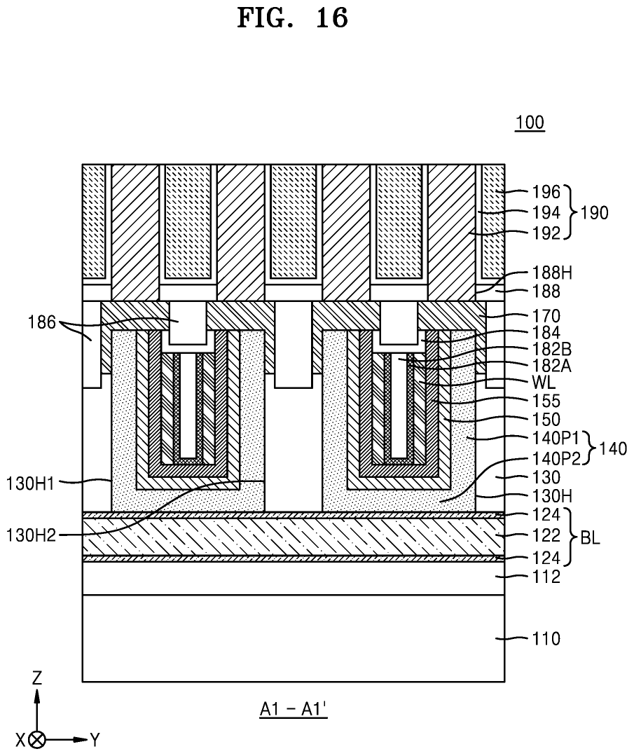

Referring to FIG. 16, the etch stop layer 188 may be formed on the contact layer 170 and the third insulating layer 186. The etch stop layer 188 may include the opening 188H, and the upper surface of the contact layer 170 may be exposed to the bottom of the opening 188H.

Thereafter, the lower electrode 192, the capacitor dielectric layer 194, and the upper electrode 196 may be sequentially formed on the etch stop layer 188.

The semiconductor device 100 may be completed by performing the processes described above.

While the present invention has been particularly shown and described with reference to embodiments thereof, it will be understood that various changes in form and details may be made therein without departing from the spirit and scope of the following claims.

What is claimed is:

1. A semiconductor device comprising:
a substrate;
a bit line extending in a first horizontal direction on the substrate;
a channel layer disposed on the bit line and including:
a first portion extending in the first horizontal direction, and
a second portion connected to the first portion, including a first sidewall and a second sidewall opposite to the first sidewall, and extending in a vertical direction perpendicular to an upper surface of the substrate;
a gate insulating layer formed to conformally cover the first portion on an upper surface of the first portion of the channel layer and the second portion on the first sidewall of the second portion of the channel layer;
a work function adjustment layer conformally formed on the gate insulating layer; and
a word line disposed on a sidewall of the work function adjustment layer and extending in a second horizontal direction perpendicular to the first horizontal direction,
wherein the channel layer includes an oxide semiconductor material.

2. The semiconductor device of claim 1, wherein the work function adjustment layer includes a material having a work function of about 4.9 eV or more.

3. The semiconductor device of claim 1, wherein:
the work function adjustment layer includes at least one of indium oxide (In₂O₃), titanium dioxide (TiO₂), molybdenum trioxide (MoO₃), and tungsten trioxide (WO₃), and
the oxide semiconductor material includes InGaZnOx (IGZO).

4. The semiconductor device of claim 1, wherein the work function adjustment layer is formed to have a thickness of about 1 nm to 20 nm.

5. The semiconductor device of claim 1, wherein:
an upper surface of the first portion of the channel layer is coplanar with a lower surface of a horizontal portion of the gate insulating layer, and
an upper surface of the word line is coplanar with an upper surface of the work function adjustment layer, and a lower surface of the word line is coplanar with a lower surface of the work function adjustment layer.

6. The semiconductor device of claim 1, wherein the uppermost surface of the second portion of the channel layer and the uppermost surface of a vertical portion of the gate insulating layer are disposed at the same vertical level.

7. The semiconductor device of claim 1, wherein a vertical portion of the work function adjustment layer has an upper surface disposed at the same vertical level as a level of an upper surface of the word line.

8. The semiconductor device of claim 1, wherein the gate insulating layer has an upper surface disposed at a level higher than an upper surface of the word line.

9. The semiconductor device of claim 1, further comprising:
a mold insulating layer disposed on the bit line and covering the second sidewall of the channel layer.

10. The semiconductor device of claim 1, further comprising:
a conductive contact pattern connected to the second portion of the channel layer; and
a capacitor structure connected to the conductive contact pattern.

11. A semiconductor device comprising:
a substrate;
a bit line extending in a first horizontal direction on the substrate;
a mold insulating layer covering the bit line on the substrate and including a mold opening;
a first cell transistor disposed on a first sidewall of the mold opening; and
a second cell transistor disposed on a second sidewall of the mold opening,
wherein each of the first cell transistor and the second cell transistor includes:
a channel layer disposed on the bit line and including:
a first portion extending in the first horizontal direction, and
a second portion connected to the first portion and extending in a vertical direction perpendicular to an upper surface of the substrate;
a work function adjustment layer disposed on the first portion and the second portion of the channel layer;
a gate insulating layer located between the channel layer and the work function adjustment layer;
a word line disposed on a sidewall of the work function adjustment layer and extending in a second horizontal direction perpendicular to the first horizontal direction; and
a contact disposed on the second portion of the channel layer,
wherein the channel layer includes an oxide semiconductor material.

12. The semiconductor device of claim 11, wherein the channel layer of the first cell transistor and the channel layer of the second cell transistor have a mirror symmetrical shape with respect to each other.

13. The semiconductor device of claim 11, wherein the work function adjustment layer is formed to have a thickness of about 1 nm to about 20 nm.

14. The semiconductor device of claim 11, wherein the work function adjustment layer includes a material having a work function of about 4.9 eV or more.

15. The semiconductor device of claim 11, wherein:
the work function adjustment layer includes at least one of indium oxide (In₂O₃), titanium dioxide (TiO₂), molybdenum trioxide (MoO₃), and tungsten trioxide (WO₃), and
the oxide semiconductor material includes InGaZnOx (IGZO).

16. The semiconductor device of claim 11, wherein:
an upper surface of the first portion of the channel layer is coplanar with a lower surface of a horizontal portion of the gate insulating layer, and
an upper surface of the word line is coplanar with an upper surface of the work function adjustment layer, and a lower surface of the word line is coplanar with a lower surface of the work function adjustment layer.

17. A semiconductor device comprising:
a substrate;
a peripheral circuit region on the substrate;
a plurality of peripheral circuits disposed in the peripheral circuit region;
a plurality of lower conductive lines disposed in parallel to each other and respectively connected to the plurality of peripheral circuits;
a mold insulation pattern disposed on the plurality of lower conductive lines and defining a transistor region extending long in a first horizontal direction;
a plurality of channel structures arranged in a row in the first horizontal direction in the transistor region and each including a vertical channel portion facing a sidewall of the mold insulation pattern;
a work function adjustment layer having a thickness of about 1 nm to about 20 nm in the transistor region and covering the plurality of channel structures;
a gate insulating layer located between the plurality of channel structures and the work function adjustment layer;
an upper conductive line disposed on the plurality of channel structures in the transistor region, having a sidewall facing the vertical channel portions of each of the plurality of channel structures, and extending long in a second horizontal direction perpendicular to the first horizontal direction; and
a plurality of conductive contact patterns connected to the vertical channel portions of the plurality of channel structures, respectively,
wherein the plurality of channel structures each includes an oxide semiconductor material, and
wherein the work function adjustment layer includes a material having a work function of about 4.9 eV or more.

18. The semiconductor device of claim 17, wherein:
the transistor region includes a plurality of transistors including the plurality of channel structures,
the plurality of transistors include two transistors facing each other in the first horizontal direction, and
the two transistors share one channel structure selected from the plurality of channel structures.

19. The semiconductor device of claim 17, wherein:
the uppermost surface of the upper conductive line is closer to the substrate than the uppermost surface of the gate insulating layer, and
an upper surface of a horizontal portion of one channel structure is coplanar with a lower surface of a horizontal portion of the gate insulating layer.

20. The semiconductor device of claim 17, wherein the work function adjustment layer includes at least one of indium oxide (In₂O₃), titanium dioxide (TiO₂), molybdenum trioxide (MoO₃), and tungsten trioxide (WO₃), and
wherein the oxide semiconductor material includes InGaZnOx (IGZO).
